(19) United States
(12) Patent Application Publication
(10) Pub. No.: US 2010/0126581 A1
(43) Pub. Date: May 27, 2010

(54) SOLAR CELL MODULE

(75) Inventors: Hirofumi Nishi, Tokyo (JP); Hirohisa Suzuki, Tokyo (JP); Katsumi Kushiya, Tokyo (JP)

Correspondence Address: CERMAK KENEALY VAIDYA & NAKAJIMA LLP, 515 EAST BRADDOCK RD SUITE B, Alexandria, VA, 22314, US

(73) Assignee: SHOWA SHELL SEKIYU K.K., Tokyo (JP)

(21) Appl. No.: 12/595,708

(22) PCT Filed: May 2, 2008
(86) PCT No.: PCT/JP2008/058419

§ 371 Date: Oct. 13, 2009

(30) Foreign Application Priority Data
May 11, 2007 (JP) 2007-126634

(51) Int. Cl. H01L 31/00; B23K 31/02; C23C 4/08

(52) U.S. Cl. 136/256; 228/101; 427/455

(57) ABSTRACT

There are provided a frameless solar cell module and a manufacturing method thereof, in which the frameless solar cell module includes a sub-module including a substrate glass, a thin-film solar cell device formed on the substrate glass, a cover glass attached to a light receiving surface side of the thin-film solar cell device, and a filler for adhering and holding the substrate glass and the cover glass, and is characterized in that lamination surfaces at side ends of the sub-module are sealed with a metal sealing material.

### TECHNICAL FIELD

The present invention relates to a technique on a solar cell module, and particularly to a technique suitable for a frameless solar cell module.

### BACKGROUND ART

A solar cell module is generally manufactured in such a way that a sub-module is manufactured by laminating a cover glass, such as a reinforced glass, on a surface of a substrate glass on which a solar cell component is laminated, while a resin such as EVA resin (ethylene-vinyl acetate copolymer resin) is used as a filler, and further, four end surfaces of the sub-module are covered with a frame made of aluminum or the like.

Fitting grooves for fitting the four end surfaces of the sub-module are provided in this frame, and the sub-module is fitted into the fitting grooves so that the solar cell module is manufactured. However, since moisture is apt to enter from the fitting portion, in general, after a resin such as butyl resin, acryl resin or silicone resin is filled in the fitting grooves, the sub-module is fitted therein, and entry of moisture from the end part is prevented to maintain weatherability.

As stated above, as the technique to prevent entry of moisture from the end part, there is proposed an end surface sealing member which is fitted in the whole periphery of the end part of a solar cell module main body, is made into the frame shape along the outer shape of the solar cell module main body, and has a multi-layer structure (see patent document 1).

Besides, in a solar cell module in which a solar cell including plural solar cell components connected in series or in parallel is sealed with an adhesive resin sealing member between a front surface protecting member and a back surface protecting member, there is proposed one in which the outer peripheral part of the adhesive resin sealing member in the peripheral part of the solar cell module includes a weatherable protecting layer made of organic polymer or mixture of the adhesive resin sealing member, and the outer peripheral part of the weatherable protecting layer, the outer peripheral part of the front surface protecting member, and the outer peripheral part of the back surface protecting member are formed on substantially the same plane in a side surface part of the solar cell module (see patent document 2).

Patent document 1: JP-A-2005-347395

Patent document 2: JP-A-2003-209273

### DISCLOSURE OF THE INVENTION

### Problems that the Invention is to Solve

However, in order to reduce the weight and manufacturing cost of the solar cell module, it is appropriate to eliminate a frame and to assemble the solar cell module from only a sub-module. However, in the technique of patent document 1, since the end surface sealing member is provided, reduction in weight and manufacturing cost cannot be achieved.

When the solar cell module is made frameless, resin such as EVA resin is exposed to the outside from a gap between the cover glass and the substrate glass, and moisture is apt to enter from the portion. Further, by exposure to the sun light, wind and rain for a long term in the open air, the resin is degraded, the entry of moisture from the portion becomes remarkable, and a short circuit between the solar cell components is caused, and the performance of the solar cell module is damaged. Accordingly, it is necessary to ensure weatherability.

In this point, in the technique disclosed in patent document 2, the peripheral part of the solar cell module is sealed with the adhesive resin. However, since the solar cell module is installed outdoors, it is impossible to avoid the degradation of the adhesive resin, and the degraded resin allows entry of moisture, and causes reduction of power generation efficiency of the solar cell module.

Then, an object of the invention is to provide a frameless solar cell module and its manufacturing method, in which a frame is eliminated to realize reduction in weight and cost of the solar cell module, and entry of moisture from the outside is prevented to maintain weatherability.

### Means for Solving the Problems

In order to achieve the above object, a frameless solar cell module of the invention is characterized in that lamination surfaces at side ends of a sub-module of a substrate glass, a thin-film solar cell device formed on the substrate glass, a cover glass attached to alight receiving surface side of the thin-film solar cell device, and a filler for adhering and holding the substrate glass and the cover glass are sealed with a metal sealing material.

Besides, a bus bar ribbon is pulled out from the lamination surfaces at the side ends of the sub-module, and on the lamination surfaces at the side ends of the sub-module, an opening part not sealed with the sealing material is provided at a portion where the bus bar ribbon is pulled out from the sub-module, and the bus bar ribbon may be pulled out from the opening part.

Besides, an insulating sleeve to allow insertion of the bus bar ribbon is attached to the sub-module at the portion where the bus bar ribbon is pulled out.

Besides, a terminal box is attached onto a back surface of the substrate glass at a portion close to the portion where the bus bar ribbon is pulled out, and the bus bar ribbon pulled out from the sub-module may be guided to the terminal box.

Besides, the sleeve and the terminal box may be integrally formed.

Besides, a manufacturing method of a frameless solar cell module of the invention is a method of manufacturing a frameless solar cell module in which lamination surfaces at side ends of a sub-module including a substrate glass, a thin-film solar cell device formed on the substrate glass, a cover glass attached to a light receiving surface side of the thin-film solar cell device, and a filler for adhering and holding the substrate glass and the cover glass are sealed with a metal sealing material, and is characterized in that a metal as the sealing material is welded onto the lamination surfaces at the side ends of the sub-module, and the lamination surfaces at the side ends are sealed.

Besides, a manufacturing method of a frameless solar cell module of the invention is a method of manufacturing a frameless solar cell module in which lamination surfaces at side ends of a sub-module including a substrate glass, a thin-film solar cell device formed on the substrate glass, a cover glass attached to a light receiving surface side of the thin-film solar cell device, and a filler for adhering and holding the substrate glass and the cover glass are sealed with a metal sealing material, and is characterized in that a metal as the sealing material is thermal sprayed onto the lamination surfaces at the side ends of the sub-module, and the lamination surfaces at the side ends are sealed.

Besides, a bus bar ribbon is pulled out from the lamination surfaces at the side ends of the sub-module, and at welding or thermal spraying of the metal onto the lamination surfaces at the side ends of the sub-module, the lamination surfaces at the side ends may be sealed except for a portion where the bus bar ribbon is pulled out from the sub-module.

### Effects of the Invention

According to the invention, a frameless solar cell module can be provided in which a frame is eliminated to realize reduction in weight and cost of the solar cell module, while entry of moisture from the outside is prevented to maintain wettability.

### BEST MODE FOR CARRYING OUT THE INVENTION

Next, embodiments of the invention will be described with reference to the drawings.

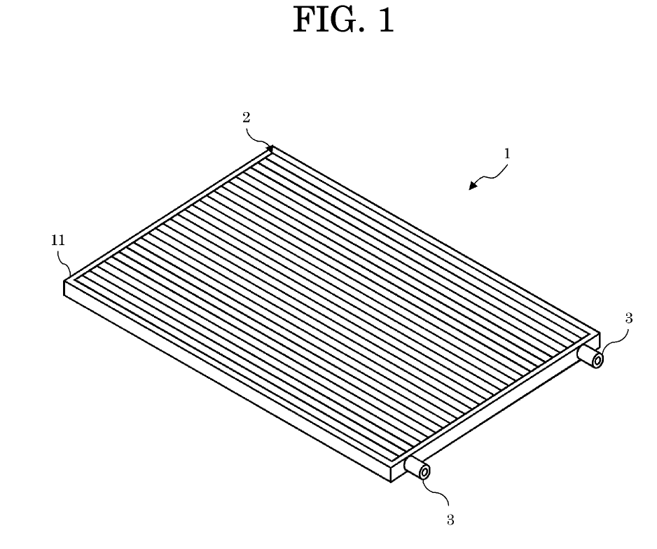

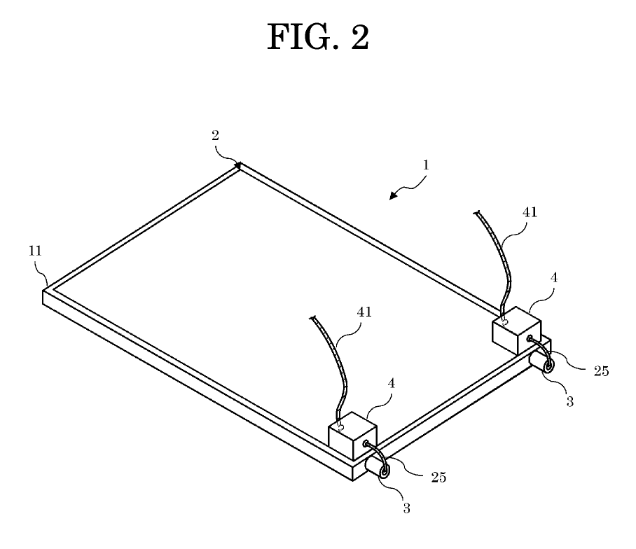

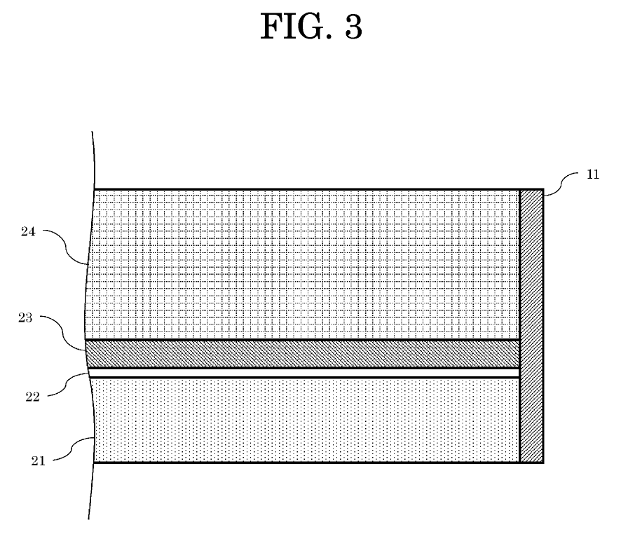

FIG. 1, FIG. 2 and FIG. 3 show a frameless solar cell module of a first embodiment.

As shown in FIG. 1, FIG. 2 and FIG. 3, a frameless solar cell module 1 includes a sub-module 2, a sleeve 3, and a terminal box 4. Lamination surfaces at side ends of the sub-module 2 are sealed with a metal 11 as a sealing material. Incidentally, the sleeve 3 may be integral with the terminal box 4.

Besides, the sub-module 2 includes a substrate glass 21, a CIS thin-film solar cell device 22 layered on the substrate glass 21 (incidentally, the CIS is CuInSe₂ compound, and is a generic term including CIS, CIGS, CIGSS, etc.), a filler 23 of EVA resin, a cover glass 24 attached to the substrate glass 21 through the filler 23, and plus and minus two bus bar ribbons 25.

Besides, a lead wire 41 is led out from the terminal box 4.

The substrate glass 21 is the substrate on which the CIS thin-film solar cell device 22 is formed. A bonded film made of, for example, fluorine resin, PET, or aluminum foil may be bonded to the back surface side of the substrate glass 21 through the filler 23 of EVA resin or the like.

The CIS thin-film solar cell device 22 is formed by laminating thin films such as a metal back surface electrode layer, a p-type light absorbing layer, a high resistance buffer layer, and an n-type window layer (transparent conductive film). This CIS thin-film solar cell device 22 receives light such as the sun light and generates electric power.

The filler 23 is embedded between the substrate glass 21 and the cover glass 24, and integrally holds these. As the filler 23, EVA resin or the like can be used, and in a state where the filler is sandwiched between the substrate glass 21 and the cover glass 24, it is heated, melted, defoamed and pressed to embed the gap, and can bond the substrate glass 21 and the cover glass 24.

The cover glass 24 is the glass provided on the light receiving surface of the frameless solar cell module 1, and can be constructed of reinforced glass having high transparency. The size of this cover glass 24 is formed to be the same as the substrate glass 21.

The metal 11 seals the lamination surfaces at the side ends as the end part opening surface on which the substrate glass 21, the CIS thin-film solar cell device 22, the filler 23 and the cover glass 24 of the sub-module 2 are laminated, and prevents entry of moisture from the lamination surfaces at the side ends.

Besides, the plus and minus two bus bar ribbons 25 are respectively pulled out from the vicinities of both ends of one lamination surface of the lamination surfaces at the side ends of the sub-module 2, and on the lamination surfaces at side ends of the sub-module 2, an opening part which is not sealed with the metal 11 is provided at the portion where the bus bar ribbon 25 is pulled out. A sleeve 3 made of highly insulating material and having a circular opening section is attached to the sub-module 2 through this opening part.

The sleeve 3 is made of insulating material such as resin and is formed into a cylindrical shape, and one of openings is attached to the sub-module 2, and the other is directed to the outside. The bus bar ribbon 25 pulled out from the sub-module 2 is pulled out to the outside through the sleeve 3, and is guided to the terminal box 4. Incidentally, in this embodiment, although the sleeve 3 has the cylindrical shape having the circular opening section, no limitation is made to this, and the opening section may be made rectangular or elliptical, or the whole shape may be made a rectangular parallelepiped shape.

At the pulling-out portion of the bus bar ribbon 25, the opening part not sealed with the metal 11 is provided, and the sleeve 3 is attached. Thus, it is possible to prevent the bus bar ribbon 25 from coming in contact with the metal 11.

On the back surface of the substrate glass 21, the two terminal boxes 4 are attached to portions close to the portions where the bus bar ribbons 25 are pulled out, the close bus bar ribbon 25 is guided to the terminal box 4 through the sleeve 3, and the bus bar ribbon 25 is electrically connected to the lead wire 41 in the terminal box 4.

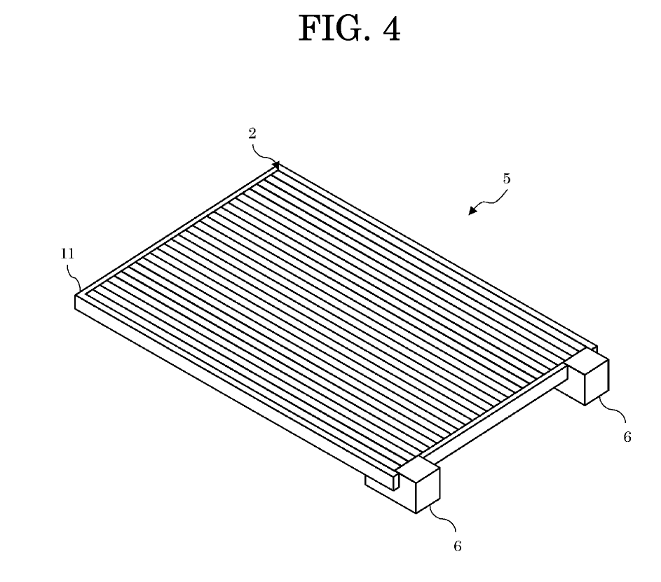

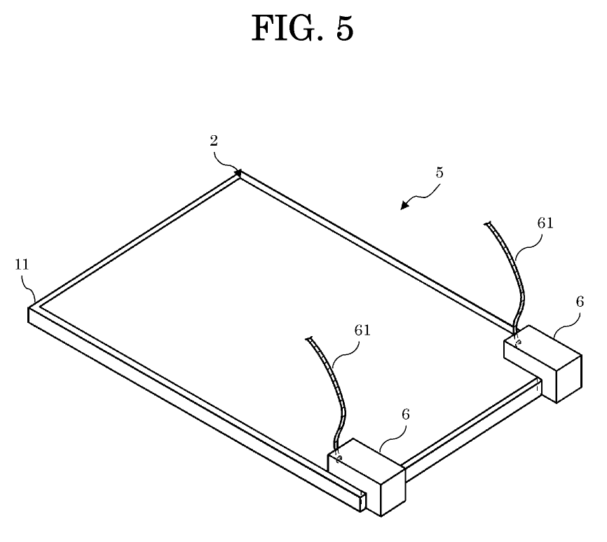

Next, a frameless solar cell module of a second embodiment of the invention will be described with reference to FIG. 4 and FIG. 5.

As shown in FIG. 4 and FIG. 5, a frameless solar cell module 5 includes a sub-module 2 having the same structure as the first embodiment, and a sleeve integral-type terminal box 6. Besides, similarly to the first embodiment, lamination surfaces at side ends of the sub-module 2 are sealed with a metal 11 as a sealing material, and entry of moisture from the lamination surfaces at the side ends is prevented.

Besides, similarly to the first embodiment, plus and minus two bus bar ribbons (not shown) are respectively pulled out from vicinities of both ends of one lamination surface of the lamination surfaces at the side ends of the sub-module 2, and on the lamination surfaces at the side ends of the sub-module 2, opening parts not sealed with the metal 11 are provided at portions where the bus bar ribbons are pulled out.

The sleeve integral-type terminal box 6 includes the sleeve 3 and the terminal box 4 of the first embodiment which are integral to each other, and is formed as a hollow body having an L-shaped bent section. The sleeve integral-type terminal box 6 is made of insulating material such as resin.

The sleeve integral-type terminal box 6 is attached to a back surface of the substrate glass 21 in such a way that a bent end part is brought into contact with an opening part of the sub-module 2, and a specified small hole provided in the end part in order to pull the bus bar ribbon into the inside is brought into contact with a bus bar ribbon pull-out port of the sub-module 2. Incidentally, the two sleeve integral-type terminal boxes 6 are attached correspondingly to the two pull-out ports of the bus bar ribbons.

The bus bar ribbon pulled out from the sub-module 2 is guided into the sleeve integral-type terminal box 6, and the bus bar ribbon is electrically connected to a lead wire 61 in the sleeve integral-type terminal box 6.

By this, the sleeve and the terminal box are integrally constructed, and the bus bar ribbon is directly pulled into the sleeve integral-type terminal box 6 from the sub-module 2. Thus, it is possible to more certainly prevent the bus bar ribbon from contacting with the metal 11, and the manufacturing process of the frameless solar cell module 5 can be simplified. Further, corrosion of the bus bar ribbon due to outdoor exposure can be effectively prevented, there is no danger of an electric shock or the like, and the safety can be increased.

Next, the manufacturing method of the frameless solar cell module 1 or 5 will be described.

With respect to the sub-module 2, first, after the CIS thin-film solar cell device 22 is formed on the substrate glass 21 by the specified related art, the filler 23 of sheet-like EVA or the like having a size of not smaller than the cover glass 24 is disposed, and the cover glass 24 is placed thereon.

The cover glass 24, the filler 23 of EVA resin or the like, and the substrate glass 21 are laminated in this order, and when they are defoamed and pressed while heating is performed by a laminator, the filler 23 of the melted EVA resin or the like firmly fixes the cover glass 24 and the substrate glass 21. When heating is further performed, the filler 23 of the EVA resin or the like is put in a cross-linked state.

Incidentally, films of the CIS thin-film solar cell device 22 are formed by laminating respective layers of a metal back surface electrode layer, a p-type light absorbing layer, a high resistance buffer layer, an n-type window layer (transparent conductive film) and the like.

The sleeve 3 or the sleeve integral-type terminal box 6 is attached to the sub-module 2, the metal 11 as the sealing material is thermal sprayed or welded onto the lamination surfaces at the side ends of the sub-module 2, and the lamination surfaces at the side ends of the sub-module 2 are sealed. When the sleeve 3 or the sleeve integral-type terminal box 6 is attached in advance, thermal spraying or welding of the metal 11 onto the pull-out portion of the bus bar ribbon 25 is prevented, and the metal 11 is put in an open state at the portion.

Various thermal spraying techniques, such as arc spraying, plasma spraying, flame spraying, welding rod spraying and wire flame spraying, can be used as the thermal spraying. Powder of the metal 11 is melted in a high temperature gas, and is blown to the sub-module 2 as the mother material at high speed, and the film is formed.

Besides, various welding techniques, such as ultrasonic welding, high frequency welding, electromagnetic welding and laser welding, can be used as the welding. For example, in the case of an ultrasonic soldering iron, since a gap between the lamination surfaces sandwiched between the side end of the cover glass 24 and the side end of the substrate glass 21 is small, the film of the metal 11 can be formed by simultaneously soldering the metal 11 to both side ends. At this time, with respect to the frequency of the ultrasonic solder, the soldering iron of 40 kHz to 70 kHz may be used.

Tin, indium or the like can be used as the sealing metal 11.

By this, the frame is eliminated to realize reduction in weight and cost of the solar cell module, and the weatherability can be maintained by preventing entry of moisture from the outside.

Incidentally, in this embodiment, although the CIS thin-film solar cell device 22 is layered on the substrate glass 21, no limitation is made to this, and another amorphous or compound thin-film solar cell device may be layered.

### BRIEF DESCRIPTION OF THE DRAWINGS

[FIG. 1] A plane perspective view showing an outer appearance of a frameless solar cell module of a first embodiment of the invention.

[FIG. 2] A back surface perspective view showing the outer appearance of the frameless solar cell module of this embodiment.

[FIG. 3] A sectional view of the frameless solar cell module of this embodiment.

[FIG. 4] A plane perspective view showing an outer appearance of a frameless solar cell module of a second embodiment of the invention.

[FIG. 5] A back surface perspective view showing the outer appearance of the frameless solar cell module of this embodiment.

### DESCRIPTION OF REFERENCE NUMERALS

1 frameless solar cell module
11 metal
2 sub-module
21 substrate glass
22 CIS thin-film solar cell device
23 filler
24 cover glass
25 bus bar ribbon
3 sleeve
4 terminal box
41 lead wire
5 frameless solar cell module
6 sleeve integral-type terminal box
61 lead wire

1. A frameless solar cell module comprising a sub-module including:
a substrate glass; a thin-film solar cell device formed on the substrate glass;
a cover glass attached to a light receiving surface side of the thin-film solar cell device; and
a filler for adhering and holding the substrate glass and the cover glass, the frameless solar cell module characterized in that
lamination surfaces at side ends of the sub-module are sealed with a metal sealing material.

2. The frameless solar cell module according to claim 1, wherein
a bus bar ribbon is pulled out from the lamination surfaces at the side ends of the sub-module,
on the lamination surfaces at the side ends of the sub-module, an opening part not sealed with the sealing material is provided at a portion where the bus bar ribbon is pulled out from the sub-module, and
the bus bar ribbon is pulled out from the opening part.

3. The frameless solar cell module according to claim 2, wherein an insulating sleeve to allow insertion of the bus bar ribbon is attached to the sub-module at the portion where the bus bar ribbon is pulled out.

4. The frameless solar cell module according to claim 2, wherein
a terminal box is attached onto a back surface of the substrate glass at a portion close to the portion where the bus bar ribbon is pulled out, and
the bus bar ribbon pulled out from the sub-module is guided to the terminal box.

5. The frameless solar cell module according to claim 3, wherein
a terminal box is attached onto a back surface of the substrate glass at a portion close to the portion where the bus bar ribbon is pulled out, and
the bus bar ribbon pulled out from the sub-module is guided to the terminal box.

6. The solar cell module according to claim 4, wherein the sleeve and the terminal box are integrally constructed.

7. The frameless solar cell module according to claim 5, wherein the sleeve and the terminal box are integrally constructed.

8. A manufacturing method of a frameless solar cell module in which lamination surfaces at side ends of a sub-module including a substrate glass, a thin-film solar cell device formed on the substrate glass, a cover glass attached to a light receiving surface side of the thin-film solar cell device, and a filler for adhering and holding the substrate glass and the cover glass are sealed with a metal sealing material, the manufacturing method of the frameless solar cell module characterized in that
a metal as the sealing material is welded onto the lamination surfaces at the side ends of the sub-module, and the lamination surfaces at the side ends are sealed.

9. A manufacturing method of a frameless solar cell module in which lamination surfaces at side ends of a sub-module including a substrate glass, a thin-film solar cell device formed on the substrate glass, a cover glass attached to a light receiving surface side of the thin-film solar cell device, and a filler for adhering and holding the substrate glass and the cover glass are sealed with a metal sealing material, the manufacturing method of the frameless solar cell module characterized in that
a metal as the sealing material is thermal sprayed onto the lamination surfaces at the side ends of the sub-module, and the lamination surfaces at the side ends are sealed.

10. The manufacturing method of the frameless solar cell module according to claim 8, wherein
a bus bar ribbon is pulled out from the lamination surfaces at the side ends of the sub-module, and
at welding or thermal spraying of the metal onto the lamination surfaces at the side ends of the sub-module, the lamination surfaces at the side ends are sealed except for a portion where the bus bar ribbon is pulled out from the sub-module.

11. The manufacturing method of the frameless solar cell module according to claim 9, wherein
a bus bar ribbon is pulled out from the lamination surfaces at the side ends of the sub-module, and
at welding or thermal spraying of the metal onto the lamination surfaces at the side ends of the sub-module, the lamination surfaces at the side ends are sealed except for a portion where the bus bar ribbon is pulled out from the sub-module.
